(19) United States
(12) Patent Application Publication
(10) Pub. No.: US 2006/0001133 A1
(43) Pub. Date: Jan. 5, 2006

(54) Optical sub-assembly for a transceiver

(76) Inventors: Brian McGarvey, County Cork (IE); Thomas Moriarty, Cork (IE)

Correspondence Address: JACOBSON HOLMAN PLLC, 400 SEVENTH STREET N.W., SUITE 600, WASHINGTON, DC, 20004, US

(21) Appl. No.: 11/226,370

(22) Filed: Sep. 15, 2005

Related U.S. Application Data
(63) Continuation of application No. PCT/IE04/00038, filed on Mar. 22, 2004.

(30) Foreign Application Priority Data
Mar. 20, 2003 (IE) IE2003/0207

(51) Int. Cl. H01L 23/495

(52) U.S. Cl. 257/666

(57) ABSTRACT

An electro-optical device (1) has a lead frame (3) having a through-hole (10) acting as a locating feature for a mould pin for moulding a body (4) incorporating a lens (5). The hole (10) is also used as a reference for a placement machine placing a component (2) within 1.5 mm of it. Subsequently, after withdrawal of the mould pin a recess (35) remains, which can act as a locating feature for a waveguide termination connecting to the device. Also, the device comprises a ground plane (55) bonded to the back of the moulded body (53) or (72) incorporated in the lead frame.

### INTRODUCTION

1. Field of the Invention

The invention relates to electro-optical devices such as transceivers, transmitters, or receivers, particularly for high frequency operation.

2. Prior Art Discussion

FIG. A shows cross-sectional front and side views of a prior art device, and FIG. B shows a side view cross-section of an assembly incorporating the device and a fibre termination. FIG. C shows a strip of metallic lead frames (LF) used during production of the device. Components such as a photo diode (PD) are placed on the lead frame (LF). These ends of the lead frame are placed in a mould in which bodies (MB) of transparent epoxy material are moulded around the ends of the lead frame (LF) and the component (PD).

After moulding, the individual parts are cut from the lead frame strip, leaving portions of the lead frame protruding from the moulded body, so as to act as electrical leads for the device. It is also known:
to incorporate a lens (L) into such moulded encapsulation;
to place a component so made into a housing (H) which forms a socket allowing a plug (P) attached to the end of an optical fibre (F) to be engaged so that the fibre is aligned with the lens; and
to incorporate a guide feature (GF) in the moulded body to assist in the alignment of the plug and the fibre with the lens.

While this approach is satisfactory in some situations, for high frequency applications it is very difficult to achieve sufficient alignment between the optical component and the moulded lens and ultimately the optical fibre.

Another aspect of high frequency electro-optical devices is that signal integrity problems arise because of discontinuity of a ground plane between the drive circuit into which the device is connected and the device itself. These problems lead to bit errors. It is known that the transmission of high frequency signals along an electrical conductor will be most effective if that electrical conductor is a constant small distance from, but insulated from, another conductor, this second conductor being connected to electrical ground. This second conductor is commonly known as the “ground plane”. In printed circuit boards, this is commonly achieved by constructing the board with multiple layers of conductors separated by insulating material. One of these layers, known as a “ground plane”, is connected to electrical ground.

In existing electro-optical device circuits there is a discontinuity in the “ground plane” effect at the point where the signal leaves a printed circuit board and enters the leads of the device. This discontinuity, though the dimensions may only be in the order of a few millimetres, can cause serious problems in the transmission of high frequency electronic signals.

The invention is therefore directed towards providing improved electro-optical devices for high-frequency operation, and methods of manufacturing them.

### SUMMARY OF THE INVENTION

According to the invention, there is provided a method of manufacturing an electro-optical device having a lead frame supporting a component and a moulded body around the component and part of the lead frame, the method comprising the steps of:
providing a locating feature in the lead frame; and
engaging a feature of the mould with the lead pin locating feature during moulding.

In one embodiment, the lead frame locating feature is used as a reference by a vision system when placing the component on the lead frame.

In another embodiment, the lead frame locating feature is within an area of the lead frame surrounded by the moulded body.

In a further embodiment, the lead frame locating feature is an aperture in the lead frame, and a mould feature is a pin.

In one embodiment, the aperture extends fully through the lead frame.

In a further embodiment, the mould pin is removed, leaving a recess in the moulded body.

In one embodiment, the recess is used subsequently as a device locating feature for connection of a fibre termination to the moulded body.

In another embodiment, a part of the fibre termination extends into the recess.

In a further embodiment, the recess is at least partially filled to prevent ingress of contaminants.

In one embodiment, the lead frame includes a spring element, allowing the part of the lead frame in which the locating feature is located to move for guiding of the mould feature into engagement.

In a further embodiment, the lead frame spring element comprises a cranked portion of a lead frame leg.

In one embodiment, the method comprises the further step of providing a ground plane in the device.

In a further embodiment, the ground plane is adhered to the moulded body.

In one embodiment, the ground plane also extends to lie alongside the exposed part of the lead frame.

In another embodiment, the ground plane is incorporated in the lead frame.

In a further embodiment, the lead frame is multi-layered, comprising:
a lead frame conducting layer,
an insulating layer, and
a ground plane layer separated from the conducting layer by the insulating layer.

In another aspect, the invention provides an electro-optical device comprising a lead frame on which is mounted a component, wherein the device further comprises a ground plane separated from a lead frame conductor.

In one embodiment, the ground plane is adhered to a moulded body encapsulated around part of the lead frame and the component.

In another embodiment, the ground plane is a layer of the lead frame.

In a further embodiment, the ground plane extends alongside an exposed part of the lead frame.

In one embodiment, the ground plane comprises legs for insertion in apertures of a circuit board.

In another embodiment, the lead frame legs are cranked to allow surface mounting of the device with the lead frame lying in the general plane of a circuit board.

The invention also provides an assembly comprising a device as defined above and a waveguide connected to the device.

The invention also provides a circuit comprising a circuit board having a ground plane and a device as defined above, wherein the ground plane of the device is electrically connected to the ground plane of the circuit board.

### DETAILED DESCRIPTION OF THE INVENTION

### BRIEF DESCRIPTION OF THE DRAWINGS

The invention will be more clearly understood from the following description of some embodiments thereof, given by way of example only with reference to the accompanying drawings in which:

FIG. 1(a) is a set of views of an electro-optical device, and FIG. 1(b) is a diagrammatic view of an alternative lead frame;

FIG. 2 is a diagrammatic side view of a device after application of a ground plane;

FIG. 3 is a diagrammatic perspective view of another device of the invention when mounted on a circuit board;

FIG. 4 is a perspective view of an alterative lead frame;

FIG. 5 is a diagrammatic side view of a further device of the invention; and

FIG. 6 is a side view of a still further device.

### DESCRIPTION OF THE EMBODIMENTS

FIG. (1) shows an electro-optical device 1 of the invention, having a photo-diode 2 mounted on a lead frame 3 and around which a transparent epoxy body 4 is moulded. The body 4 incorporates a lens 5.

The lead frame 3 comprises a locating hole 10 close to the component 2 and within the moulded body 4. Section A-A shows registry of the component 2 with the lens 5. Very accurate registry is achieved because the locating hole 10 provides a reference during moulding because a moulding pin is inserted in it, thus allowing highly accurate moulding and hence location of the lens 5 with respect to the component 2. The lead frame locating hole 10 provides a rigid link between the lead frame in close proximity to the component 2 and the mould body. The dimensions of the locating hole are typically 1 mm in diameter and the distance from the component 2 to the centre of the locating hole is typically 1.5 mm.

As shown in the B-B Section, after removal of the mould pin from the hole 10 there is a deep recess 35. This is partially filled in a subsequent operation with polymer 36, leaving a more shallow recess for use in alignment of the end of a waveguide.

The locating feature on the lead frame is also used as the reference by the machine placing the electro-optical component 2, thus allowing even greater accuracy. Thus, the locating hole 10 provides a single reference for both component placement and moulding. This is particularly advantageous for the level of accuracy required for high frequency use of the device.

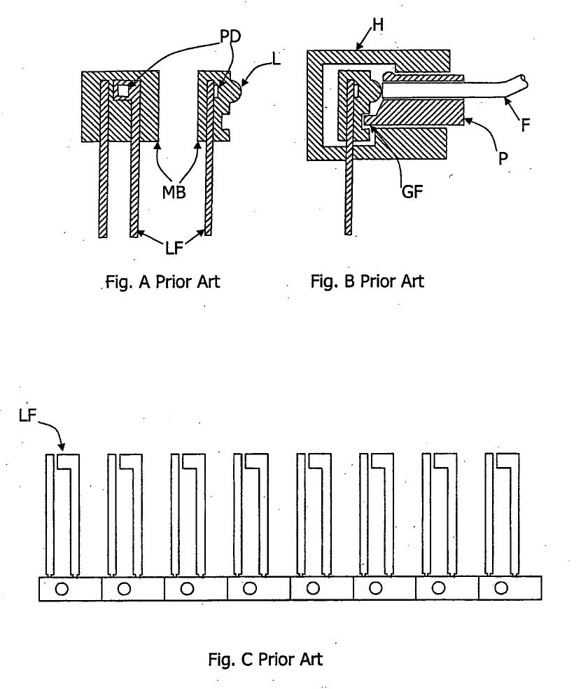

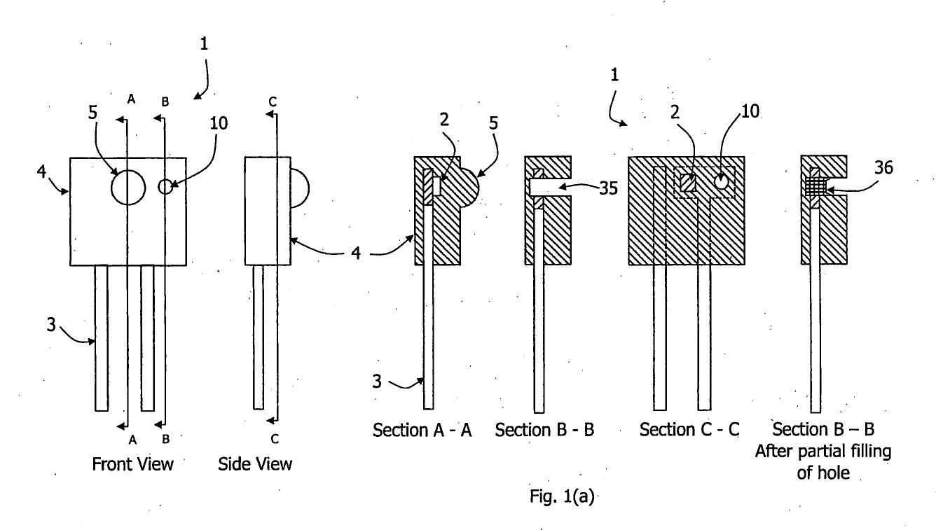

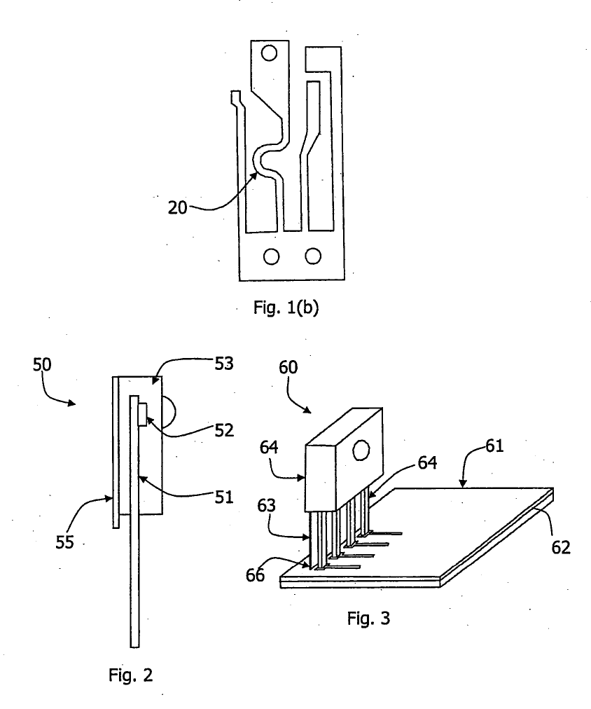

Turning again to the moulding, as the lead frame is inserted into the mould the tapered end of the mould pin will engage in the hole 10, and guide it to the correct location relative to the mould. To facilitate this guiding action, it may be advantageous to incorporate resilience in a part of the lead frame to allow the portion of the lead frame carrying the electro-optical component and the locating hole to move relative to the rest of the lead frame, so as to allow it to be guided by the pin. This is illustrated in FIG. 1(b), which is similar in function to the lead frame shown in FIG. 1(a), except that the member carrying the locating hole has a curved support portion 20, providing a spring effect between the lower main strip with the tooling holes and the point where the locating pin accurately positions the portion of the lead frame carrying the electro-optical component.

As mentioned above the effect of the pin will be to leave a hole in the finished moulded component. After completion of the moulding operation, this is partially filled to prevent the ingress of moisture to the lead frame at a point dose to the location of the electro-optical component.

The shape of the pin is such that this hole, (or as much of it as remains after part of it is filled) acts as a locating element for the light guide, or for a carrier which locates the light guide or optical fibre in the correct location relative to the lens or other appropriate feature on the device.

In an alternative embodiment, the locating feature may be located just outside the portion of the lead frame that is encapsulated in the mould. In this case the pin or other feature of the mould that locates the locating feature will not leave an impression in the finished moulded part, but the provision of such a locating pin or other locating mechanism close to the electro-optical component in each cavity of the mould will serve to precisely locate the electro-optical components relative to the moulded features.

Referring to FIG. 2, in a further method step for producing a device 50 having a lead frame 51, a component 52, and a moulded body 53, a ground plane 55 is bonded at the rear surface of the body 53. The ground plane 55 may be connected by a soldered link to the circuit board's ground plane. This provides continuity between the circuit board's ground plane, and that of the device.

Referring to FIG. 3 a device 60 is shown mounted in a circuit board 61 having a ground plane 62. A ground plane 63 is adhered to the back of a moulded body 64, and it extends down at the back of the lead frame 64. At the board level it is located in holes 66 for electrical connection with the circuit's ground plane 62.

Thus the signals flowing in the tracks parallel to the ground plane 62 continue to be a similar distance from the ground plane 63 as they flow up the leads formed by the lead frame 64.

However, other arrangements are possible. The leads could be bent to facilitate surface mounting, or the component may be inserted in an appropriate socket or connected to wires or other discrete conductors.

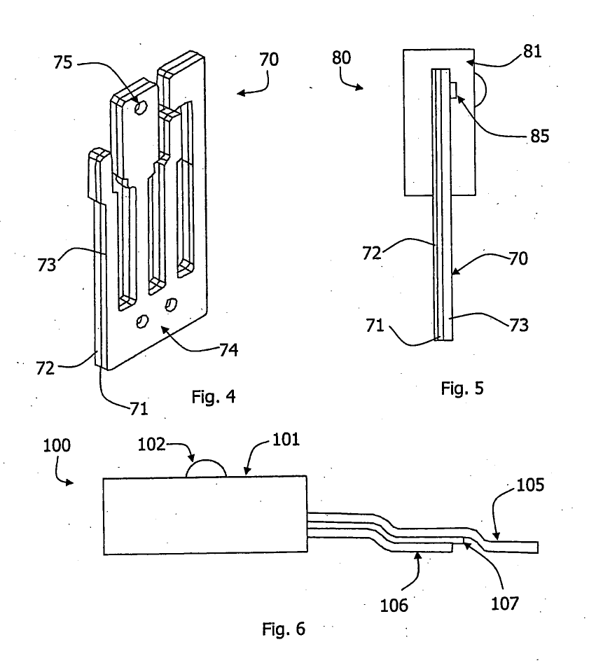

In another embodiment the lead frame material is assembled with the ground plane material and a thin layer of insulating material, which is between them. This is then used as a basis on which to mount the electronic or electro-optical components. This construction is illustrated in FIGS. 4 and 5. FIG. 4 shows a lead frame 70 prepared with insulating material 71, ground plane material 72, and conducting material 73. An additional member 74 on the bottom serves to hold the elements of the lead frame together until the moulding operation has been completed. This element 74 will be cut away after moulding. This drawing shows a locating hole 75 close to where a component is placed.

In FIG. 5 the whole device is shown, including a moulded body 81 and an electro-optical component 85 which is mounted on the signal-carrying layer 73 of the lead frame 70. The ground plane layer of the lead frame, 72, is separated from the signal-carrying layer 73 by the insulating layer 71.

Parts made according to this construction may be particularly suitable for surface mounting, by arranging for the lead or leads corresponding to the ground plane to be longer than, shorter than, or shaped differently from the other leads and for one or both sets of leads to be bent to bring them to the same plane. This is illustrated in FIG. 6, showing a device 100 with a body 101 and a lens 102 moulded on a composite lead frame consisting of a signal carrying layer 105 and a ground plane layer 106, both of metal, with an intermediate insulating layer 107. The leads formed by the portions of the lead frame which protrude from the body of the component are bent so that when the component is laid flat on a printed circuit board, the ground plane leads and the signal leads will all come in contact with different portions of the printed circuit board, to which they may be attached by solder.

The distance between the conductor carrying the high frequency signal and the ground plane should be altered if the dielectric constant of the material between them changes. Thus, for example, if the dielectric constant of the material used between the lead frame and the ground plane in the device is different from the dielectric constant of the material used between the signal conductor and the ground plane conductor in the printed circuit board, it may be appropriate that the distance between the first pair be correspondingly greater or less than the distance between the latter pair. For example, fr4 PCB material has a dielectric constant of 4.6 and the gap between the active layer and ground plane is 0.30 mm. Optical plastic package material has a typical dielectric constant of 3.8. So the distance between the data leads and ground plane within the package should be set to 0.25 mm provided the data leads are the same width inside the package as they are outside. The impedance may also be matched by adjusting the data lead width in cases where the thickness of package cannot be adjusted.

It will be appreciated that the invention provides for elimination of the manufacturing error in lead frame dimensions between tooling hole and reference. Location of the moulded body is made by the same reference as is used for the vision system of the component placing machine. Errors arising from relative thermal expansion of the lead frame and the moulded body are reduced by a large factor because of the short distance between the component placement position and the locating hole. The invention also reduces errors in mould dimensions and registry between the lens and the fibre if the mould pin recess is used for registration of the fibre termination. It will also be appreciated that the invention provides for significantly enhanced electro-optical performance because of the ground plane arrangement.

The invention is not limited to the embodiments described but may be varied in construction and detail.

1-29. (canceled)

30. A method of manufacturing an electro-optical device having a lead frame supporting a component and a moulded body around the component and part of the lead frame, the method comprising the steps of:
providing a locating feature in the lead frame;
engaging a feature of the mould with the lead frame locating feature during moulding; and
the lead frame including a spring element allowing the part of the lead frame in which the locating feature is located to move for guiding engagement with the mould feature.

31. The method as claimed in claim 30, wherein the lead frame comprises a base and a plurality of legs extending from the base, at least one of said legs having the locating feature and the spring element, the spring element being between the locating feature and the base.

32. The method as claimed in claim 30, wherein the lead frame locating feature is used as a reference by a vision system when placing the component on the lead frame.

33. The method as claimed in claim 30, wherein the lead frame locating feature is within an area of the lead frame surrounded by the moulded body.

34. The method as claimed in claim 30, wherein the lead frame locating feature is an aperture in the lead frame, and a mould feature is a pin.

35. The method as claimed in claim 34, wherein the aperture extends fully through the lead frame.

36. The method as claimed in claim 34, wherein the mould pin is removed, leaving a recess in the moulded body.

37. The method as claimed in claim 36, wherein the recess is used subsequently as a device locating feature for connection of a fibre termination to the moulded body.

38. The method as claimed in claim 37, wherein a part of the fibre termination extends into the recess.

39. The method as claimed in claim 36, wherein the recess is at least partially filled to prevent ingress of contaminants.

40. The method as claimed in claim 30, wherein the lead frame spring element comprises a cranked portion of a lead frame leg.

41. The method as claimed in claim 30, comprising the further step of providing a ground plane in the device.

42. The method as claimed in claim 41, wherein the ground plane is adhered to the moulded body.

43. The method as claimed in claim 42, wherein the ground plane also extends to lie alongside the exposed part of the lead frame.

44. The method as claimed in claim 41, wherein the ground plane is incorporated in the lead frame.

45. The method as claimed in claim 44, wherein the lead frame is multi-layered, comprising:
a lead frame conducting layer,
an insulating layer, and
a ground plane layer separated from the conducting layer by the insulating layer.

46. The electro-optical device manufactured in a method according to claim 30 comprising a lead frame on which is mounted a component, wherein the device further comprises a ground plane separated from a lead frame conductor.

47. The electro-optical device as claimed in claim 46, wherein the ground plane is adhered to a moulded body encapsulated around part of the lead frame and the component.

48. The electro-optical device as claimed in claim 46, wherein the ground plane is a layer of the lead frame.

49. The electro-optical device as claimed in claim 46, wherein the ground plane extends alongside an exposed part of the lead frame.

50. The electro-optical device as claimed in claim 49, wherein the ground plane comprises legs for insertion in apertures of a circuit board.

51. The electro-optical device as claimed in claim 48, wherein the lead frame legs are cranked to allow surface mounting of the device with the lead frame lying in the general plane of a circuit board.

52. The assembly comprising a device of claim 46, and a waveguide connected to the device.

53. The circuit comprising a circuit board having a ground plane and a device of claim 46, wherein the ground plane of the device is electrically connected to the ground plane of the circuit board.
